(19) United States
(12) Patent Application Publication
(10) Pub. No.: US 2003/0038661 A1
(43) Pub. Date: Feb. 27, 2003

(54) Apparatus to decrease the spurs level in a phase-locked loop

(76) Inventors: Ramesh Chokkalingam, Irvine, CA (US); Matteo Conta, Irvine, CA (US); Farbod Behbahani, Santa Ana, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/207,007

(22) Filed: Jul. 26, 2002

Related U.S. Application Data
(60) Provisional application No. 60/308,430, filed on Jul. 27, 2001.

(51) Int. Cl. H03L 7/06

(52) U.S. Cl. 327/157

(57) ABSTRACT

A charge pump is disclosed including an output capacitive element to store an output voltage, a charging current source to charge the output capacitive element, a charging switching element to couple a first bias voltage to the charging current source in response to a charging signal, a discharging current source to discharge the output capacitive element, a discharging switching element to couple a second bias voltage to the discharging current source in response to a discharging signal, a unity gain amplifier to generate an amplifier voltage substantially equal to the output voltage, a first switching element to couple the amplifier voltage to the charging current source in response to a leakage prevention signal; and a second switching element to couple the amplifier voltage to the discharging current source in response to the leakage prevention signal.

### CROSS-REFERENCE TO RELATED APPLICATION

This application claims the benefit of the filing date of U.S. patent application, Ser. No. 60/308,430, filed on Jul. 27, 2001, and entitled “An Apparatus to Decrease the Spurs Level in a Phase-Locked Loop.”

### FIELD OF THE INVENTION

This invention relates generally to phase-locked loop circuits, and in particular, to a phase-locked loop method that reduces leakage of charge to the control input of a voltage controlled oscillator (VCO) to reduce spurs and phase noise.

### BACKGROUND OF THE INVENTION

FIG. 1 illustrates a block diagram of an exemplary phase-locked loop circuit 100. The phase-locked loop circuit 100 comprises a crystal oscillator 102, a phase frequency detector 104, a charge pump 106, a loop filter 108, a voltage controlled oscillator (VCO) 110, and a frequency divider 112. The phase-locked loop circuit 100 generates a periodic signal at a frequency f_{vco}.In order to control the frequency stability of the output signal f_{vco}, the output signal f_{vco} is divided down by the frequency divider by a factor of N to form a divided output signal cycling with a frequency of f_{vco}/N. The PFD 104 compares the divided output signal f_{vco}/N to the reference signal fₓ from crystal oscillator 102 and generates up- and down-signals. If the divided output signal frequency f_{vco}/N is below the crystal oscillator reference frequency fₓ, the PFD 104 produces one or more up-pulses. If the output-sampled signal frequency f_{vco}/N is above the crystal oscillator reference frequency fₓ, the PFD 104 produces one or more down-pulses.

The charge pump 106 receives the up- and down-pulse signals from the PFD 104 and generates an output voltage that varies positively with the number of received up-pulses and negatively with the number of down-pulses. The output voltage of the charge pump 106 is filtered by the loop filter 108 and then applied to the frequency control input of the VCO 110. In this example, the frequency f_{vco} of the VCO 110 varies in the same direction as the output voltage of the charge pump 106.

In operation, if the VCO output frequency f_{vco} is below the desired frequency as determined by the PFD 104 comparing the divided output signal f_{vco}/N to the crystal reference fₓ, the PFD 104 issues up-pulses to increase the output voltage of the charge pump 106, thereby increasing the frequency f_{vco} of the VCO 110 until the divided output signal f_{vco}/N substantially equals the crystal reference frequency fₓ. If the VCO output frequency f_{vco} is above the desired frequency as determined by the PFD 104 comparing the divided output signal f_{vco}/N to the crystal reference fₓ, the PFD 104 issues down-pulses to decrease the output voltage of the charge pump 106, thereby decreasing the frequency f_{vco} of the VCO 110 until the divided output signal f_{vco}/N substantially equals the crystal reference frequency fₓ.

FIG. 2 illustrates a block/schematic diagram of a prior art PFD 200. The PFD 200 consists of a first D-flip-flop 202 having an input to receive the crystal oscillator reference frequency fₓ, a second D-flip-flop 204 having an input to receive the divided output signal f_{vco}/N, a logic AND-gate 206 having inputs to receive the outputs of the D-flip-flops 202 and 204, and a delay 208 coupled to the output of the AND-gate 206 and the reset inputs of the D-flip-flops 202 and 204. The up- and down-pulses are produced at the respective outputs of the D-flip-flops 202 and 204.

In operation, if the rising edge of the reference signal fₓ arrives first (meaning that the output frequency of the VCO is below the desired frequency), the up-signal at output of the D-flip-flop 202 stays on longer than the down-signal at the output of the D-flip-flop 204. Thus, the net effect is that the charge pump increases its output voltage to increase the frequency of the VCO. If, on the other hand, the rising edge of the divided output signal f_{vco}/N arrives first (meaning that the output frequency of the VCO is above the desired frequency), the down-signal at output of the D-flip-flop 204 stays on longer than the up-signal at the output of the D-flip-flop 202. Thus, the net effect is that the charge pump decreases its output voltage to decrease the frequency of the VCO.

FIG. 3 illustrates a schematic diagram of a prior art source-switched charge pump 300. The charge pump 300 consists of a charging switching transistor 302 having a gate to receive the up-pulses from a PFD, a charging current source 304, a discharging current source 306, and a discharging switching transistor 308 having a gate to receive the down pulses from the PFD. The charging switching transistor 302, the charging current source 304, the discharging current source 306, and the discharging switching transistor 308 are connected in series between VDD and ground. The output capacitor C of the charge pump 305 is coupled to the node between the charging and discharging current sources 304 and 306.

In operation, during the on-time of an up-pulse, the charging switching transistor 302 conducts and couples VDD to the charging current source 304. The charging current source 304 then begins sending charges to the output capacitor C to cause the output voltage of the charge pump 300 to increase.. Conversely, during the on-time of a down-pulse, the discharging switching transistor 308 conducts and couples the discharging current source 306 to ground. The discharging current source 306 removes charges from the output capacitor C to cause the output voltage of the charge pump 300 to decrease.

A problem with the prior art source-switched charge pump 300 occurs when the charge pump is in tristated state (i.e. when both the charging switching transistor 302 and discharging transistor 308 are off). When both transistors 302 and 308 are off, stray charges may be present on the terminals of the current sources 304 and 306. However, since both transistors 302 and 308 are off, the only available path for these charges to propagate is the path to the output of the charge pump 300. Therefore, these stray charges leak to the output of the charge pump which has the adverse effect of generating spurs in the output signal of the VCO as well as increase the phase noise of the output signal.

Thus, there is a need for a phase-locked loop circuit, charge pump and related methods that overcome the drawback of the prior art phase-locked loop circuit and charge pump.

### BRIEF DESCRIPTION OF THE DRAWINGS

FIG. 1 illustrates a schematic/block diagram of an exemplary phase-locked loop circuit;

FIG. 2 illustrates a schematic/block diagram of a prior art phase frequency detector (PFD);

FIG. 3 illustrates a schematic/block diagram of a prior art charge pump;

FIG. 4 illustrates a schematic/block diagram of an exemplary charge pump in accordance with the invention;

FIG. 5 illustrates a schematic/block diagram with details of the exemplary charge pump in accordance with the invention; and

FIG. 6 illustrates a block diagram of an exemplary leakage pulse generator in accordance with the invention.

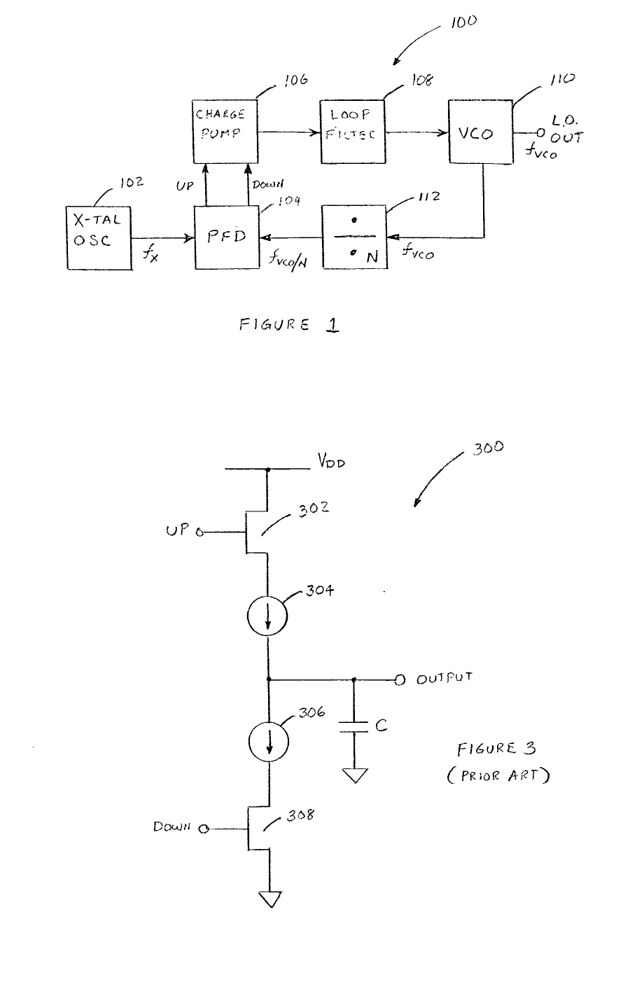

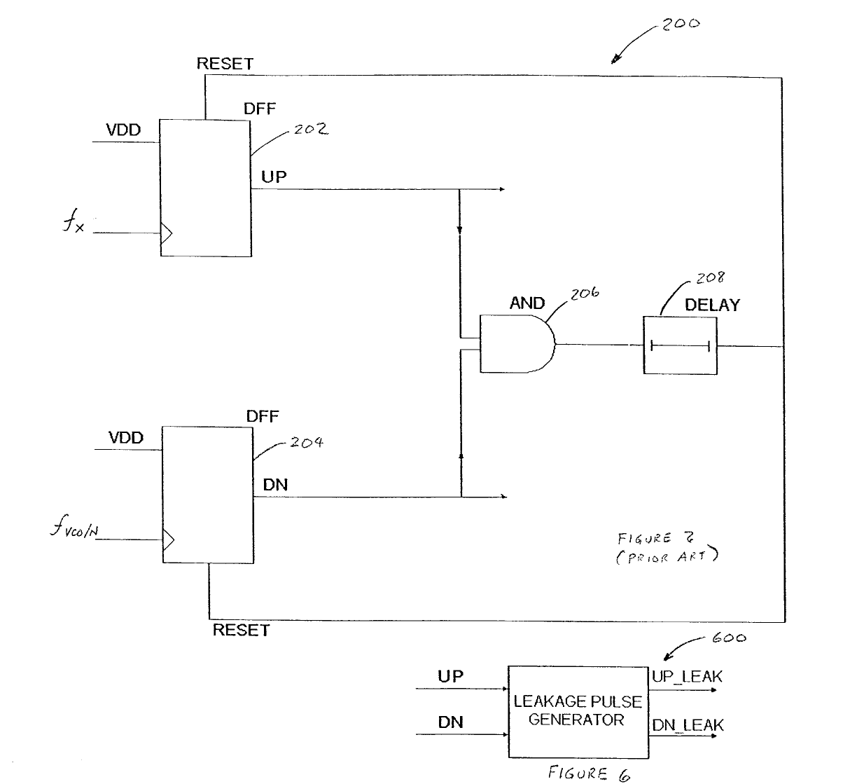

### DETAILED DESCRIPTION OF THE INVENTION

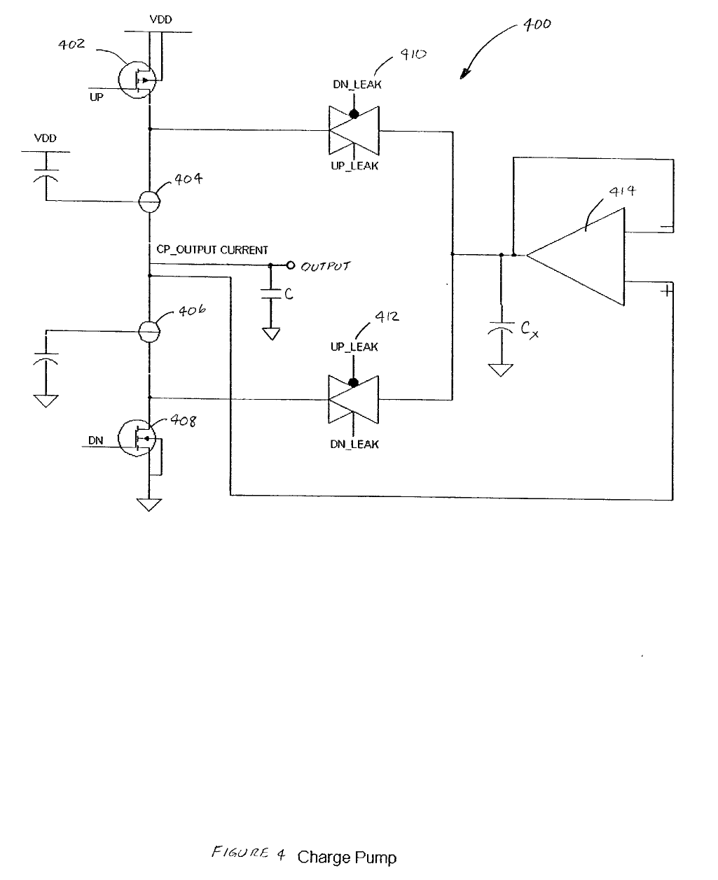

FIG. 4 illustrates a schematic/block diagram of an exemplary source-switched charge pump 400 in accordance with the invention. The charge pump 400 comprises a charging switching transistor 402 having a gate to receive the up-pulses from a PFD, a charging current source 404, a discharging current source 406, and a discharging switching transistor 408 having a gate to receive the down-pulses from the PFD. The charging switching transistor 402, the charging current source 404, the discharging current source 406, and the discharging switching transistor 408 are connected in series between VDD and ground. The output capacitor C of the charge pump 400 is coupled to the node between the charging and discharging current sources 404 and 406.

In order to remove stray charges that may reside in the charging and discharging current sources 404 and 406 and prevent them from propagating to the charge pump output, the source-switched charge pump 400 of the invention further comprises a first pass gate 410, a second pass gate 412, an operational amplifier 414, and an additional capacitor Cx. The first pass gate 410 is connected to the output of the operational amplifier 414 and to the node between the charging switching transistor 402 and the charging current source 404. The second pass gate 412 is connected to the output of the operational amplifier 414 and to the node between the discharging switching transistor 408 and the discharging current source 406. The operational amplifier 414 is connected in a unity gain configuration, having its positive input terminal connected to the output of the charge pump 400 and its negative input terminal connected to its output. The capacitor Cx is connected to the output of the operational amplifier 414 and ground potential.

In operation, when the charge pump 400 is tristated (i.e. the D-flip-flips of the PFD have been reset and the up- and down-signals are in a logic low state), both the charging and discharging switching transistors are 402 and 408 are off. This leaves the respective nodes between the charging switching transistor 402 and the charging current source 404 and between the discharging switching transistor 408 and the discharging current source 406 floating. Without any compensation as provided by the circuitry of the invention, the voltage on these floating nodes slowing migrate to the output voltage of the charge pump 400. Such charge migration can produce spurs at the output of the VCO as well as increase the phase noise of the VCO output signal.

When the charge pump 400 is in a tristated state, pulses UP_LEAK AND DN_LEAK are sent to the pass gates 410 and 412 to turn on the pass gates 410 and 412. When the pass gate 410 is on, it couples the output of the operational amplifier 414 to the node between the charging switching transistor 402 and the charging current source 404. Since the operational amplifier 414 is in a unity gain configuration with the output of the charge pump 400 as its input, the output voltage of the charge pump 400 is generated at the output of the operational amplifier 414. The pass gate 410 couples this voltage to the node between the charging switching transistor 402 and the charging current source 404, thereby producing substantially no voltage difference across the charging current source 404, which prevents or at least slows down charge migration across the charging current source 404 to the output of the charge pump 400. The same effect occurs to the discharging current source 406 when pass gate 412 is on.

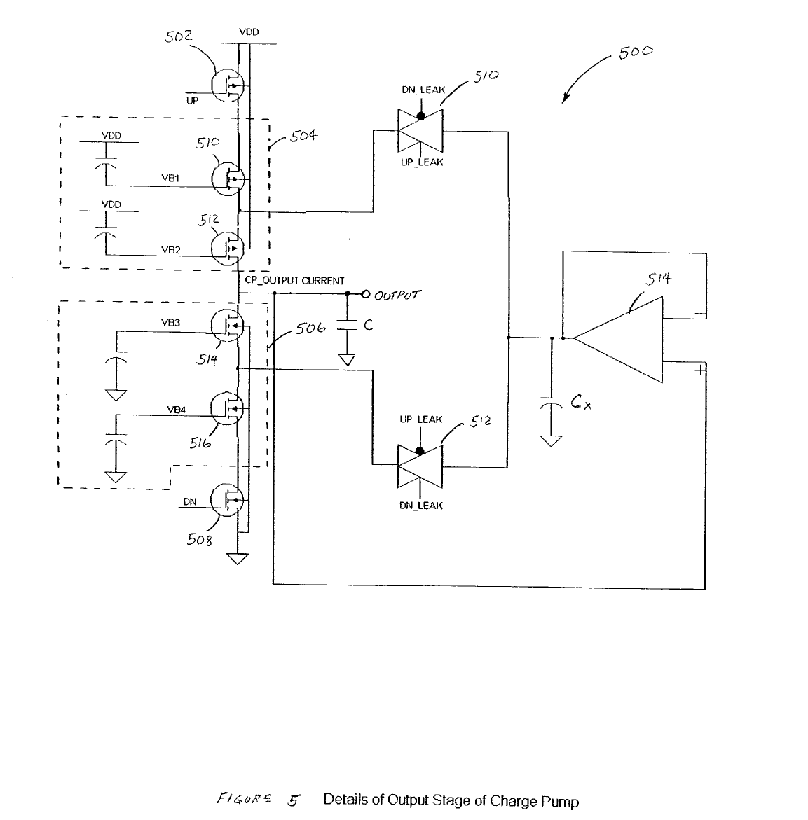

FIG. 5 illustrates a schematic/block diagram with details of exemplary source-switched charge pump 500 in accordance with the invention. The charge pump 500 comprises a charging switching transistor 502 having a gate to receive the up-pulses from a PFD, a charging current source 504, a discharging current source 506, and a discharging switching transistor 508 having a gate to receive the down-pulses from the PFD. The charging switching transistor 502, the charging current source 504, the discharging current source 506, and the discharging switching transistor 508 are connected in series between VDD and ground. The output capacitor C of the charge pump 500 is coupled to the node between the charging and discharging current sources 504 and 506.

The charging current source 504, in turn, comprises a current source transistor 510 and a cascode transistor 512. The discharging current source 506, in turn, comprises a current source transistor 514 and a cascode transistor 516. The gates of the transistors 510, 512, 514, and 516 have capacitors on them to supply the transient current during switching and prevent the gate voltage from varying. Transients on the gate input affect the drain current and can slow down the charge pump. These capacitors speed up the rise time of the output current pulse.

Charge pump 500 includes circuitry to prevent or at least reduce charge migration to and from the output of the charge pump. The leakage reduction circuit comprises the pass gates 510 and 512, the operational amplifier 514, and the capacitor Cx. In this case, the pass gate 510 is connected to the node between the cascode transistor 510 and the current source transistor 512, and the pass gate 512 is connected to the node between the current source transistor 514 and the cascode transistor 516. When tristated, pulses UP_LEAK and DN_LEAK are sent to the pass gates 510 and 512 to turn on the pass gates 510 and 512. This action causes the voltage across the transistors 512 and 514 to be substantially zero so that migration of charges is prevented, as discussed above with reference to charge pump 400.

FIG. 6 illustrates a block diagram of an exemplary leakage pulse generator 600 in accordance with the invention. The leakage pulse generator 600 receives as inputs the up- and down-signals from the PFD, and produces the UP_LEAK and DOWN_LEAK signals for the charge pump. When both the up- and down-signals are logically low (meaning that the charge pump is in a tristated state), the leakage pulse generator 600 produces the UP_LEAK and DOWN_LEAK signals to drive the pass gates of the charge pump of the invention.

In the foregoing specification, the invention has been described with reference to specific embodiments thereof. It will, however, be evident that various modifications and changes may be made thereto without departing from the broader spirit and scope of the invention. The specification and drawings are, accordingly, to be regarded in an illustrative rather than a restrictive sense.

What is claimed is:

1. A charge pump, comprising:
an output capacitive element to store an output voltage;
a charging current source to charge said output capacitive element;
a charging switching element to couple a first bias voltage to said charging current source in response to a charging signal;
a discharging current source to discharge said output capacitive element;
a discharging switching element to couple a second bias voltage to said discharging current source in response to a discharging signal;
a unity gain amplifier to generate an amplifier voltage substantially equal to said output voltage;
a first switching element to couple said amplifier voltage to said charging current source in response to a leakage prevention signal; and
a second switching element to couple said amplifier voltage to said discharging current source in response to said leakage prevention signal.

2. The charge pump of claim 1, wherein said output capacitive element comprises a capacitor.

3. The charge pump of claim 1, wherein said charging switching element comprises a field effect transistor.

4. The charge pump of claim 1, wherein said discharging switching element comprises a field effect transistor.

5. The charge pump of claim 1, wherein said first switching element comprises a pass gate.

6. The charge pump of claim 1, wherein said second switching element comprises a pass gate.

7. The charge pump of claim 1, further comprising a capacitor coupled to an output of said unity gain amplifier.

8. A method comprising:
providing an output capacitive element that stores an output voltage;
providing a charging circuit to charge said output capacitive element in response to a charging signal;
providing a discharging circuit to discharge said output capacitive element in response to a discharging signal;
removing said charging and discharging signals such that said output voltage floats; and
coupling said output voltage to a second voltage substantially equal to said output voltage in response to a leakage prevention signal.

9. The method of claim 8, wherein coupling said output voltage to a second voltage is performed by a switching element.

10. The method of claim 9, wherein said switching element comprises a pass gate.

11. The method of claim 8, further comprising generating said second voltage.

12. The method of claim 11, wherein generating said second voltage includes applying said output voltage to a unity gain amplifier.

13. A charge pump, comprising:
an output capacitive element to store an output voltage;
a first charging current source to charge said output capacitive element;
a second charging current source to charge said output capacitive element;
a charging switching element to couple a first bias voltage to said first charging current source in response to a charging signal;
a first discharging current source to discharge said output capacitive element;
a second discharging current source to discharge said output capacitive element;
a discharging switching element to couple a second bias voltage to said second discharging current source in response to a discharging signal;
a unity gain amplifier to generate an amplifier voltage substantially equal to said output voltage;
a first switching element to couple said amplifier voltage to said charging current source in response to a leakage prevention signal; and
a second switching element to couple said amplifier voltage to said discharging current source in response to said leakage prevention signal.

14. The charge pump of claim 13, wherein said output capacitive element comprises a capacitor.

15. The charge pump of claim 13, wherein said charging switching element comprises a field effect transistor.

16. The charge pump of claim 13, wherein said discharging switching element comprises a field effect transistor.

17. The charge pump of claim 13, wherein said first switching element comprises a pass gate.

18. The charge pump of claim 13, wherein said second switching element comprises a pass gate.

19. The charge pump of claim 13, further comprising a capacitor coupled to an output of said unity gain amplifier.
